(19) United States
(12) Patent Application Publication
(10) Pub. No.: US 2025/0356904 A1
(43) Pub. Date: Nov. 20, 2025

(54) TCCD SPECIFICATION FOR SCALING BANDWIDTH ON HIGH BANDWIDTH MEMORY DEVICES AND ASSOCIATED SYSTEMS AND METHODS

(71) Applicant: Micron Technology, Inc., Boise, ID (US)

(72) Inventor: Sujeet Ayyapureddi, Boise, ID (US)

(21) Appl. No.: 19/201,689

(22) Filed: May 7, 2025

Related U.S. Application Data
(60) Provisional application No. 63/647,493, filed on May 14, 2024.

(51) Int. Cl. G11C 11/4076; G11C 11/4093; G11C 11/4096

(52) U.S. Cl. CPC G11C 11/4076; G11C 11/4093; G11C 11/4096

(57) ABSTRACT

A system-in-package (SiP) device can include a base substrate and a processing unit. The SiP can also include a high bandwidth memory (HBM) device electrically coupled to the processing unit. The HBM device can also include a plurality of stacks, with each stack having a plurality of bank groups associated with a same channel or pseudo-channel. Based on a timing parameter communicated from the HBM device, the processing unit can be configured to transmit a first command to a first bank group associated with a first stack and configured to transmit a second command to a second bank group associated with the first stack no less than t_{CCDS_SID} clock (CLK) cycles after transmitting the first command. The t_{CCDS_SID} is a ratio of t_{CCDL}/t_{CCDS} and is greater than 2.

### CROSS-REFERENCE TO RELATED APPLICATION(S)

The present application claims priority to U.S. Provisional Patent Application No. 63/647,493, filed May 14, 2024, the disclosure of which is incorporated herein by reference in its entirety.

### TECHNICAL FIELD

The present technology is generally related to vertically stacked semiconductor devices and more specifically to vertically stacked high bandwidth storage devices for semiconductor packages.

### BACKGROUND

Microelectronic devices, such as memory devices, microprocessors, and other electronics, typically include one or more semiconductor dies mounted to a substrate and encased in a protective covering. The semiconductor dies include functional features, such as memory cells, processor circuits, imager devices, interconnecting circuitry, etc. To meet continual demands on decreasing size, wafers, individual semiconductor dies, and/or active components are typically manufactured in bulk, singulated, and then stacked on a support substrate (e.g., a printed circuit board (PCB) or other suitable substrates). The stacked dies can then be coupled to the support substrate (sometimes also referred to as a package substrate) through substrate (or silicon) vias (TSVs) between the dies and the support substrate.

### BRIEF DESCRIPTION OF THE DRAWINGS

FIG. 1 is a partially schematic cross-sectional diagram of a related art system-in-package device.

FIG. 2 is a simplified related art timing diagram for data flow through the TSVs.

FIG. 3A is a partially schematic cross-sectional diagram of a system-in-package device that is consistent with the present disclosure.

FIG. 3B is a block diagram of an embodiment of a HBM device that is consistent with the present disclosure.

FIG. 4 is a block diagram of an embodiment of a transmit/receive circuit that can be used in the TSVs of FIGS. 3A and 3B.

FIG. 5A is a simplified timing diagram for data flow through the DQ and TSV buses during write operations that is consistent with the present disclosure.

FIG. 5B is a simplified timing diagram for data flow through the DQ and TSV buses during read operations that is consistent with the present disclosure.

FIG. 6 is a block diagram of another embodiment of a HBM device that is consistent with the present disclosure.

FIG. 7A is a simplified timing diagram for data flow through the DQ and TSV buses during write operations that is consistent with the present disclosure.

FIG. 7B is a simplified timing diagram for data flow through the DQ and TSV buses during read operations that is consistent with the present disclosure.

FIG. 8 is a flow chart that shows a method of transmitting commands from a host device that is consistent with the present disclosure.

The drawings have not necessarily been drawn to scale. Further, it will be understood that several of the drawings have been drawn schematically and/or partially schematically. Similarly, some components and/or operations can be separated into different blocks or combined into a single block for the purpose of discussing some of the implementations of the present technology. Moreover, while the technology is amenable to various modifications and alternative forms, specific implementations have been shown by way of example in the drawings and are described in detail below. The intention, however, is not to limit the technology to the particular implementations described.

### DETAILED DESCRIPTION

High data reliability, high speed of memory access, higher data bandwidth, lower power consumption, and reduced chip size are features that are demanded from semiconductor memory. In recent years, vertically stacked memory devices have been introduced, often referred to as 2.5-dimensional (“2.5D”) memory devices when placed adjacent to a host device or 3-dimensional (“3D”) memory devices when stacked on top of the host device. Some 2.5D and 3D memory devices are formed by stacking memory dies vertically and interconnecting the dies using through-silicon (or through-substrate) vias (TSVs). The memory dies can be grouped in “stacks” with each stack, designated by a stack ID (“SID”), having one or more dies (e.g., 4 dies). Benefits of the 2.5D and 3D memory devices include shorter interconnects (which reduce circuit delays and power consumption), a large number of vertical vias between layers (which allow wide bandwidth buses between functional blocks, such as memory dies, in different layers), and a considerably smaller footprint. Thus, the 2.5 and 3D memory devices contribute to higher memory access speed, lower power consumption, and chip size reduction. Example 2.5D and/or 3D memory devices include Hybrid Memory Cube (HMC) and High Bandwidth Memory (HBM). For example, HBM is a type of memory that includes a vertical stack of dynamic random-access memory (DRAM) dies and an interface die (which, e.g., provides the interface between the DRAM dies of the HBM device and a host device). In the description below, the terms “stack” and “SID” are used interchangeably.

In a system-in-package (SiP) configuration, HBM devices may be integrated with a host device (e.g., a graphics processing unit (GPU), computer processing unit (CPU), a tensor processing unit (TCU), and/or any other suitable processing unit) using a base substrate (e.g., a silicon interposer, a substrate of organic material, a substrate of inorganic material and/or any other suitable material that provides interconnection between GPU/CPU and the HBM device and/or provides mechanical support for the components of a SiP device) through which the HBM devices and host communicate. Because traffic between the HBM devices and host device resides within the SiP (e.g., using signals routed through the silicon interposer), a higher bandwidth may be achieved between the HBM devices and host device than in conventional systems. In other words, the TSVs interconnecting DRAM dies within an HBM device, and the silicon interposer integrating HBM devices and a host device, enable the routing of a greater number of signals (e.g., wider data buses) than is typically found between packaged memory devices and a host device (e.g., through a printed circuit board (PCB)). The high bandwidth interface within a SiP enables large amounts of data to move quickly between the host device (e.g., GPU/CPU/TCU, etc.) and HBM devices during operation. For example, the high bandwidth channels can be on the order of 1000 gigabytes per second (GB/s, sometimes also referred to as gigabits (Gb)). As a result, the SiP device can quickly complete computing operations once data is loaded into the HBM devices. SiP devices, in turn, are typically integrated with a package substrate (e.g., a PCB) adjacent to other electronics and/or other SiP devices within a packaged system. It will be appreciated that such high bandwidth data transfer between the host device and the memory of HBM devices can be advantageous in various high-performance computing applications, such as video rendering, high-resolution graphics applications, artificial intelligence and/or machine learning (AI/ML) computing systems and other complex computational systems, and/or various other computing applications.

Market demands on SiP devices and/or the HBM devices therein can present certain challenges, however. One such challenge is that demands on SiP devices (and the HBM devices therein) require the devices to continually increase bandwidth and corresponding DQ pin data rates. The increased data rates means that the data paths in the HBM device operate at tight timing margins. For example, the timing parameter t_{CCDR}, which corresponds to 2 CLK cycles, can degrade. In addition, increasing the bandwidth can mean changing the memory array timing, which is not desirable. Accordingly, it is desirable to increase the bandwidth on the HBM device while maintaining the same memory array timing and keeping t_{CCDR} CLK cycles at 2 CLK cycles.

As used herein, the terms “vertical,” “lateral,” “upper,” “lower,” “top,” and “bottom” can refer to relative directions or positions of features in the devices in view of the orientation shown in the drawings. For example, “bottom” can refer to a feature positioned closer to the bottom of a page than another feature. These terms, however, should be construed broadly to include devices having other orientations, such as inverted or inclined orientations where top/bottom, over/under, above/below, up/down, and left/right can be interchanged depending on the orientation.

Further, although primarily discussed herein in the context of 2.5 HBM devices for SiP devices, one of skill in the art will understand that the scope of the present disclosure is not so limited. For example, various components of the SiP devices described herein can also be implemented in 3D HBM devices and various other stacked semiconductor devices to help with issues related to high data rates as discussed above. Accordingly, the scope of the present disclosure is not confined to any subset of embodiments and is confined only by the limitations set out in the appended claims.

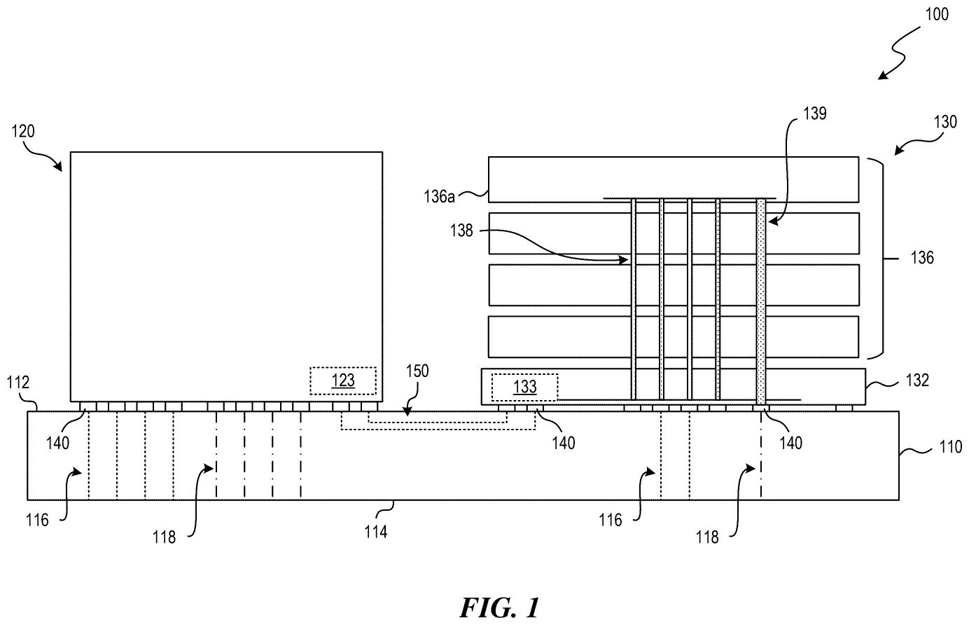

FIG. 1 is a partially schematic cross-sectional diagram of a related art SiP device 100. As illustrated in FIG. 1, the SiP device 100 includes a base substrate 110 (e.g., a silicon interposer, another organic interposer, an inorganic interposer, and/or any other suitable base substrate), as well as a host device 120 and an HBM device 130 each integrated with (e.g., carried by and coupled to) an upper surface 112 of the base substrate 110 through a plurality of interconnect structures 140 (three labeled in FIG. 1). The interconnect structures 140 can be solder structures (e.g., solder balls), metal-metal bonds, and/or any other suitable conductive structure that mechanically and electrically couples the base substrate 110 to each of the host device 120 and the HBM device 130. Further, the host device 120 is coupled to the HBM device 130 through one or more communication channels 150 formed in the base substrate 110. The communication channels 150 can include one or more route lines (two illustrated schematically in FIG. 1) formed into (or on) the base substrate 110.

As further illustrated in FIG. 1, the base substrate 110 includes a plurality of external signal TSVs 116 and a plurality of external power TSVs 118 extending between the upper surface 112 and a lower surface 114 of the base substrate 110. The external signal TSVs 116 can communicate signals (e.g., data, control signals, processing commands, and/or the like) between the host device 120 and/or the HBM device 130 and an external component (e.g., a PCB the base substrate 110 is integrated with, an external controller, and/or the like). The external power TSVs 118 provide electrical power to the host device 120 and/or the HBM device 130 from an external power source.

In the illustrated environment, the host device 120 can include a variety of components, such as a processing unit (e.g., CPU/GPU/TCU, etc.), one or more registers, one or more cache memories, and/or a variety of other components. For example, in the illustrated environment, the host device 120 includes a host IO circuit 123 that can direct signals to and/or from the HBM device 130 through the communication channels 150. Additionally, or alternatively, the host IO circuit 123 can direct signals to and/or from an external component (e.g., a controller coupled to one or more of the external signal TSVs 116 and/or the like).

The HBM device 130 can include an interface die 132 and a stack of one or more memory stacks 136 (four illustrated in FIG. 1) carried by the interface die 132. Each of the memory stacks 136 can include one or more DRAM dies (not shown in FIG. 1). Each memory stack 136 may encompass a physical and/or logical arrangement of one or more dies and can be associated with a stack ID (SID). The HBM device 130 also includes one or more signal TSVs 138 (four illustrated in FIG. 1) and one or more power TSVs 139 (one illustrated in FIG. 1) each extending from the interface die 132 to an uppermost memory stack 136a. The power TSV(s) 139 provide power (e.g., received from one or more of the external power TSVs 118) to the interface die 132 and each of the memory stacks 136. The signal TSVs 138, which include TSVs for carrying control, address, and DQ signals, communicably couple a corresponding memory die in each of the memory stacks 136 to a HBM memory controller circuit 133 in the interface die 132 (in addition to various other circuits in the interface die 132). In turn, the HBM memory controller circuit 133 can direct DQ, control, and/or address signals to and/or from the host device 120 and/or an external component (e.g., an external storage device coupled to one or more of the external signal TSVs 116 and/or the like).

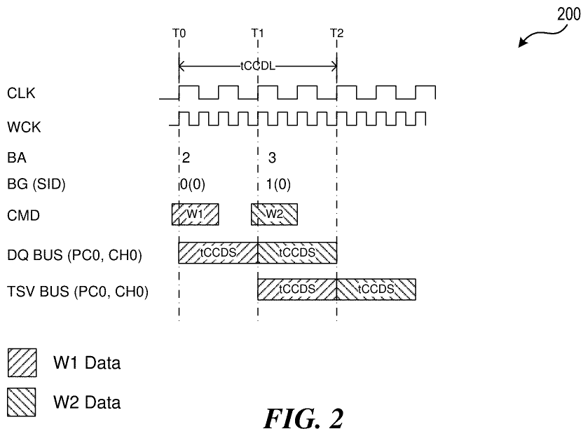

FIG. 2 illustrates a timing diagram 200 for a related art SiP that shows data transfer during a write operation using a set of TSVs (“TSV bus”). The timing diagram can correspond to a related art HBM device with a data rate of 8 Gbps. For brevity, a read timing diagram is not shown. As used herein a “TSV bus” can refer to one or more TSVs carrying DQ signals. For example, based on the context, a TSV bus can refer to all the TSVs or a subset of the TSVs in an HBM device (e.g., TSVs corresponding to a channel, a pseudo-channel, etc.). As seen in FIG. 2, the frequency of the system clock CLK determines the frequency of the write clock WCK, which can be, for example, twice the system CLK frequency. The WCK signal provides the timing for data transfer using, for example, double data rate (DDR). That is, data transfers occur on both the rising and falling edges of the WCK clock.

The CLK signal determines the duration of timing parameters, such as for example, column access timing parameters t_{CCDL}, t_{CCDS} and t_{CCDR}, which can be set according to the standard for the HBM device. The timing parameter t_{CCDL} is the read/write (RD/WR) command delay between different banks (BAs) within the same bank group (BG), the timing parameter t_{CCDS} is the RD/WR command delay between different BGs, and the timing parameter t_{CCDR} is the RD command delay between different SIDs. The host device and the HBM device communicate using an interface protocol, which is provided to and/or configured in the host device prior to the start of memory operations. The timing parameters are part of the interface protocol between a host device and HBM device, and the HBM device may provide to the host device the timing requirements for scheduling memory operations. That is, the HBM device may let the host device know the CLK cycle settings for timing parameters such as, for example, t_{CCDL} and t_{CCDS}. The host device observes any restrictions in the timing parameters when communicating with the HBM device. For example, based on the t_{CCDL} timing parameter, the host device will not schedule read or write commands to banks in the same bank group within the same t_{CCDL} CLK cycle period. That is, after sending a command (e.g., read, write, etc.) to a bank in a bank group, the host device will wait t_{CCDL} CLK cycles (e.g., 4 CLK cycles in related art SiPs) before scheduling another read or write command to a bank in the same bank group. With respect to the timing parameter t_{CCDS}, after a read or write command to a bank in a bank group, the host device will wait t_{CCDS} CLK cycles before scheduling another read or write command to a bank in a different bank group. The host device will not violate the timing protocols when scheduling memory commands to the HBM device. That is, the host device will wait at least the number of cycles specified by a timing parameter before issuing successive commands that implicate a timing parameter (e.g., certain timing parameters specify a minimum number of cycles in between commands of certain types). Those skilled in the art understand the interface protocol between the host device and the HBM device and thus, for brevity, will not be further discussed except as needed to explain embodiments of the present disclosure.

As seen in timing diagram 200, the t_{CCDL} CLK cycle period is set to 4 CLK cycles and the t_{CCDS} CLK cycle period is set to 2 CLKs. The timing parameters are set to ensure that the timings of the memory arrays in the dies, the timing through the TSV bus, and the timings of the DQ bus are synchronized to ensure proper operation of the HBM device. For example, in a related art HBM device having a CLK frequency of 2 GHz and a bitrate of 8 gigabits per second (Gbps) (using a burst length of 8), the t_{CCDL} CLK cycle period is set to 4 CLK cycles and the t_{CCDS} CLK cycle period is set to 2 CLK cycles to synchronize data transfer between an HBM device and a host device so as to keep the DQ bus saturated (e.g., DQ bus for PC0, channel 0). That is, as seen in FIG. 2, to maintain the 8 Gbps rate, the DQ bus corresponding to a channel or pseudo-channel is available for write operations every 2 CLK cycles (e.g., a new set of 32-byte pseudo-channel data is available for transmission on the DQ bus every 2 CLK cycles). Similarly, for read operations (not shown), the DQ bus will be available to receive new 32-byte pseudo-channel data every 2 CLK cycles.

As seen in FIG. 2, two BGs can be accessed during a t_{CCDL} CLK cycle period (4 CLK cycles), such as, for example, bank 2 in BG0/SID1 and bank 3 in BG1/SID0. Once the W1 write command to bank 2 in BG 3 is issued, the host device (e.g., host device 120) will wait t_{CCDS} CLK cycles (2 CLK cycles) before issuing the W2 write command to bank 3 in BG1. Depending on how the bank groups are arranged in the HBM device, the BGs can be in the same stack or in different stacks. As seen in FIG. 2, the two write commands to BG0 and BG1 take t_{CCDL} CLK cycles (4 CLK cycles). So, t_{CCDL} CLK cycles after scheduling the W1 write command to BG0, the host device can schedule another write command to a different bank in BG0, if needed. Prior to the completion of t_{CCDL} CLK cycles after the first command, the host device will not issue another command to the same bank group.

For purposes of explanation, it is assumed that BG0 and BG1 are in the same SID and use the same TSV bus (e.g., same set of TSVs corresponding to PC0, CH0) for communicating with the DQ bus (e.g., DQ bus for PC0, CH0). Also, for clarity, the W1 data flow and the W2 data flow are identified with hashed lines going in different directions. At time T0, based on a write command W1 to bank 2 of BG0 with a BL of 8, 32 bytes of data are transmitted using 2 CLK cycles (4 WCK cycles) to the DQ bus. At time T1, the W1 data is transferred to bank 2 over the TSV bus, which communicatively couples to BG0. As seen in FIG. 2, the transmission to bank 2 of BG 3 takes t_{CCDS} CLK cycles (2 CLK cycles). Still at time T1, based on a write command W2 to bank 3 of BG1, 32 bytes of data are transmitted to the DQ bus after W1 data transfer to the DQ bus has finished. At time T2, the W1 data is finished transferring over the TSV bus for BG0. The W1 data transfer over the TSV bus takes a t_{CCDS} CLK cycles (2 CLK cycles), at which point the TSV bus is free to be used for another transfer. At time T2, the W2 data is transferred over the TSV bus, which communicatively couples to BG1. In the related art system of FIG. 2, the HBM device uses a t_{CCDL} CLK cycle period of 4 CLK cycles and a t_{CCDS} CLK cycle period of 2 CLK cycles to ensure that the memory array timing, the TSV bus timing, the DQ bus timing are synchronized, so that data is not lost and the DQ bus is saturated.

There is, however, a need to increase bandwidth of the communication between the host device and the HBM device on, e.g., communication channels 350 (e.g., from a data rate of 8 Gbps to greater than 8 Gbps such as, for example, 16 Gbps, 24 Gbps, 32 Gbps or more). Details on HBM devices, SiP devices having HBM devices, and associated systems and methods consistent with the present disclosure are set out below. For ease of reference, simplified assemblies of semiconductor packages (and their components) are described herein. It is to be understood, however, that the semiconductor assemblies (and their components) can be moved to, and used in, different spatial orientations without changing the structure and/or function of the disclosed embodiments of the present technology. Additionally, embodiments of the semiconductor packages (and their components) are sometimes described herein with reference to control, read, and/or write signals. It is to be understood, however, that the signals can be described using other terminology and/or the embodiments can use other types of signals that are not discussed without changing the structure and/or function of the disclosed embodiments of the present technology.

To achieve increased bandwidth, more BGs can be opened up (e.g., per channel or per pseudo-channel) for read/write operation during, for example, the t_{CCDL} CLK cycle period and the data rate at the DQ pins can be increased accordingly. However, one potential issue is that, because the data paths in the HBM device operate at tight timing margins, an increase in the data rate at the DQ pins can result in a slip in the timing margins. That is, an increased data rate can mean that the memory array timing, the TSV bus timing, and/or the DQ bus timing are no longer synchronized. A solution can be to increase the t_{CCDS} and t_{CCDR} CLK cycle periods (e.g., setting them to 3 or 4 CLK cycles instead of 2 CLK cycles) to ensure data is not lost when transferring from/to the DQ bus, which operates at a timing of t_{CCDS} CLK cycles (2 CLK cycles) based on external requirements. However, by waiting extra CLK cycles, the data transfers in the HBM device can be less efficient because the DQ bus may no longer be saturated (e.g., gaps or bubbles may exist when there is no data to process).

Another potential issue is that memory array timings are set such that read/write operations on a BG require access to the TSV bus for a predetermined period of time. For example, a related art HBM device can perform read/write operations at an 8 Gbps data rate on two BGs during a t_{CCDL} CLK cycle period (see FIG. 2). For each read/write operation, the memory array timings require access to the appropriate TSV bus for 2 CLK cycles (1 ns) before the TSV bus can be released for the next read/write operation. Thus, the t_{CCDL} CLK cycle in the related art HBM device is set to 4 CLK cycles (2 ns) to accommodate the two BGs opened during the t_{CCDL} CLK cycle period. Accordingly, with a t_{CCDL} CLK cycle period of 4 CLK cycles (time duration of 2 ns) and a t_{CCDS} CLK cycle period of 2 CLK cycles (time duration of 1 ns), the memory array timing is synchronized with the TSV bus timing and the DQ bus timing in the related art HBM device. Even in a case where the sequential write operations are to bank groups in the same SID (as shown in FIG. 2), the timing remains synchronized such that data is not lost and the DQ bus is saturated.

If the number of BGs and the data rate at the DQ bus are increased in order to increase bandwidth in an HBM device, the memory array timings will no longer be synchronized with the TSV bus timings and/or the DQ bus timings. For example, if the data rate is doubled from 8 Gbps to 16 Gbps, with a t_{CCDL} CLK cycle period of 4 CLK cycles and a t_{CCDS} CLK cycle period of 2 CLK cycles, the t_{CCDL} time duration will go from 2 ns to 1 ns and the t_{CCDS} time duration will go from 1 ns to 0.5 ns. As discussed above, the memory array timings are synchronized when the t_{CCDL} time duration is 2 ns and the t_{CCDS} time duration is 1 ns. While the TSV bus frequency can be increased to match the higher data rate and keep the t_{CCDS} CLK cycle period at 2 CLK cycles, the memory arrays may not be able to cycle through the increased number of bank groups in less than 2 ns, and changing the timing in the memory array architecture to match a t_{CCDL} time duration of 1 ns may not be feasible and/or cost effective because of its complexity.

A potential option that may allow the t_{CCDL} CLK cycles to remain at 4 CLK cycles (a time duration of 1 ns) is to open two bank groups for access at the same time. This option keeps the memory array timing in synchronization and also accommodates the increased data rate. However, such a design means that the two bank groups are fixedly paired and must be accessed as a single unit. This configuration effectively reduces the number of independently addressable bank groups and thus reduces the flexibility of the HBM device memory scheduler in selecting memory banks during read/write operations. Accordingly, it is desirable to increase the bandwidth of HBM devices without changing the memory array structure of related art HBM devices (e.g., HBM devices following the JEDEC Standard, High Bandwidth Memory DRAM (HBM4) Specification) and/or changing the number of addressable bank groups.

Embodiments of the present disclosure enable an increased bandwidth in comparison to related art HBM devices. To increase the bandwidth, the number of BGs accessed during a t_{CCDL} CLK cycle period can be increased (e.g., per channel or per pseudo-channel). For example, three or more BGs can be opened (e.g., per channel or per pseudo-channel) during t_{CCDL} CLK cycle period to increase the bandwidth of the HBM device. In addition, the t_{CCDL} CLK cycle setting can be extended (e.g., to 8 CLK cycles, 12 CLK cycles, 16 CLK cycles, etc.) accordingly to accommodate the greater number of BGs, and the timing parameters t_{CCDS} and t_{CCDR} can be set at 2 CLK cycles to keep the DQ bus saturated. In addition, in some embodiments, a new timing parameter t_{CCDS_SID} is introduced as a specification change for commands to different bank groups in the same SID. The new timing parameter t_{CCDS_SID} is defined as a delay between read or write commands associated with different bank groups in the same stack (SID).

In some embodiments, an HBM device can have a data rate of 16 Gbps with a system clock CLK frequency of 4 GHz. The number of BGs that are opened (e.g., per channel or per pseudo-channel) can be 4 to accommodate the increased bandwidth and the t_{CCDL} CLK cycle period can be set to, for example, 8 CLK cycles (2 ns) to accommodate the 4 BGs. In addition, in some embodiments, the t_{CCDS} CLK cycle period is set to, for example, 2 CLK cycles (0.5 ns) based on the 16 Gbps data rate to keep the DQ bus saturated and keep the DQ bus and TSV bus synchronized. Because the t_{CCDL} time duration is maintained at 2 ns by increasing the t_{CCDL} CLK cycles to 8 CLK cycles, the memory array timing need not be changed to accommodate the higher bandwidth of embodiments of the present disclosure. Additional details of embodiments of the present disclosure are discussed below.

In the following discussion, reference will be made to DQ pins, channels, pseudo-channels, and corresponding TSVs. Those skilled in the art understand that, depending on the architecture of the HBM device, the number of TSVs per DQ pin can be a relationship that is something other than a one-to-one ratio. For example, based on a burst length (BL) of 8, there can be 8 TSVs per DQ pin. Depending on the design, other HBM devices can have other TSVs/DQ pin ratios such as, for example, 4 TSVs/DQ pin, 1 TSV/DQ pin, etc. Accordingly, while the following discussion focuses on TSV buses and DQ pins, those skilled in the art understand that more than one TSV can correspond to a DQ pin even if not explicitly stated. In addition, in the following discussion, the TSV bus and/or the DQ bus can correspond to, for example, a channel, a pseudo channel, or some other grouping of data lines.

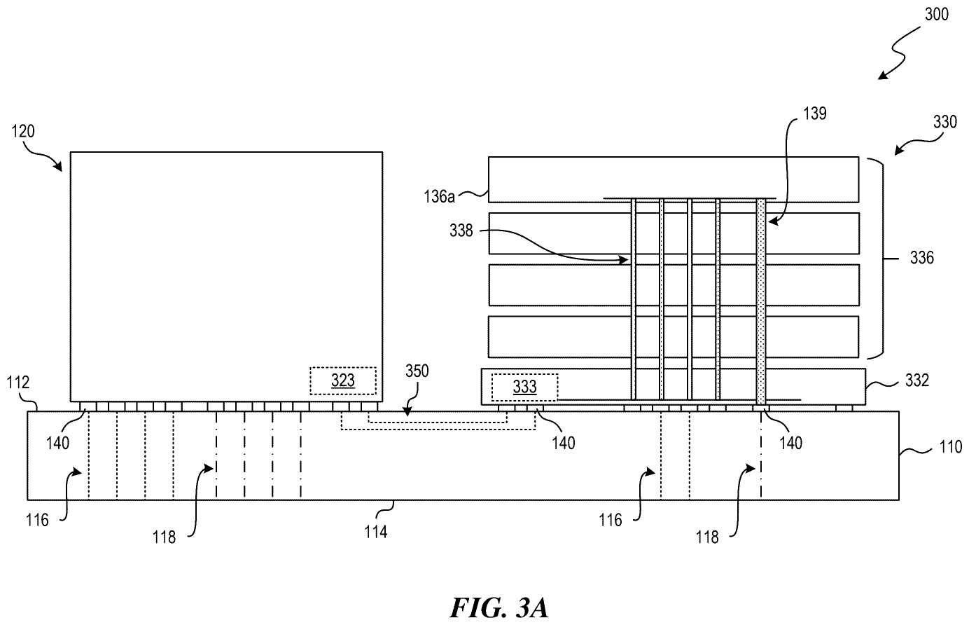

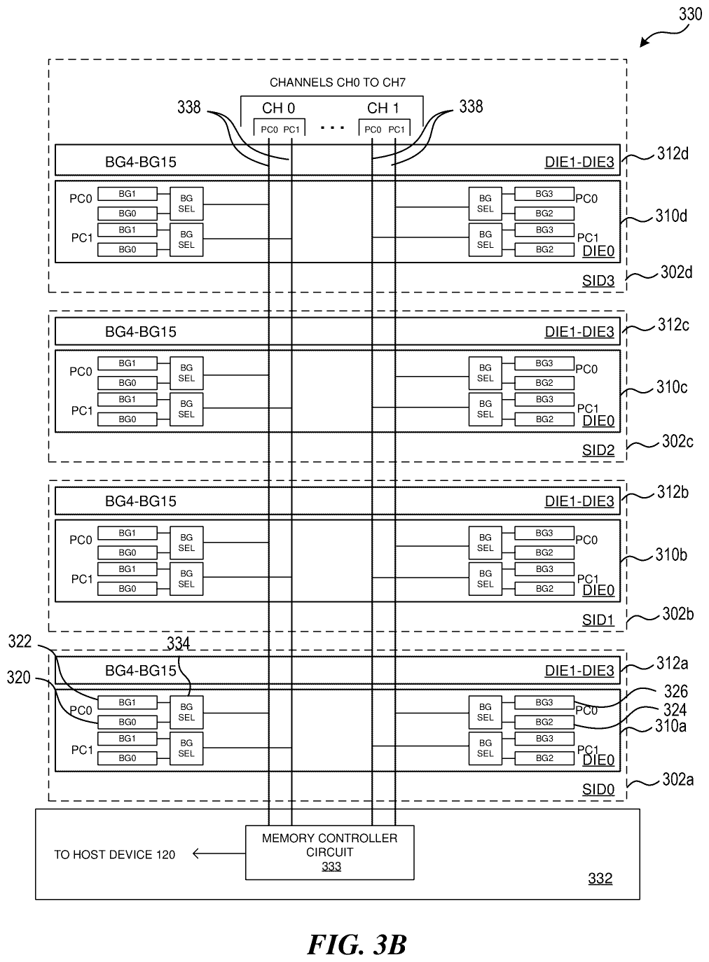

FIG. 3A is a partially schematic cross-sectional diagram of an embodiment of a SiP device 300 that is consistent with the present disclosure. SiP device 300 is similar to SiP device 100 and components that are the same are identified with the same reference numbers. Accordingly, the functions of those components will not be discussed further. Host IO circuit 323, HBM memory controller circuit 333, interface die 332, signal TSVs 338, and communication channel 350 have the same functions as Host IO circuit 123, HBM memory controller circuit 133, interface die 132, signal TSVs 138, and communication channel 150, respectively, as discussed above with respect to FIG. 1. However, in some embodiments, these components can be configured to and/or may include different circuits to handle an increased data rate (e.g., 16 Gbps, 24 Gbps, 32 Gbps, etc.). In addition, stacks 336 can have a different configuration than stacks 136 in FIG. 1, as discussed below.

FIG. 3B illustrates a block diagram of the HBM device 330 of FIG. 3A. The illustrated embodiment in FIG. 3B has a 4N architecture in that the HBM device 330 includes four stacks SID0-SID3, which can be the same as stacks 336 in FIG. 3A, and each of the stacks SID0-SID3 (labeled 302a-d, respectively) can include four DRAM dies DIE0-DIE3 (die DIE0 in each stack is labeled 310a-d, respectively, and dies DIE1-DIE3, in each stack are collectively labeled 312a-d, respectively). However, other embodiments can have other arrangements in which the number of stacks and/or dies can be fewer or greater. For example, in some embodiments, the number of stacks and/or dies can be 1, 2, or 3.

Each die 310a-d and 312a-d can have one or more channels that provide independent data access to one or more banks of memory arrays (not shown). For example, in the embodiment of FIG. 3B, channels 0 and 1 and the corresponding pseudo-channels PC0 and PC1 for each channel are shown extending through the stacks 302a-d using TSV buses. Each pseudo-channel TSV bus can include one or more TSVs 338 (one TSV 338 on each TSV bus is illustrated in FIG. 3B), depending on the burst length and number of DQ pins in each channel. Die 310a-d in each stack has bank groups BG0 320 and BG1 322 (for clarity, only BG0 and BG1 in stack 302a and die 310a are labeled), which can communicatively couple to channel 0, and bank groups BG2 324 and BG3 326 (for clarity, only BG0 and BG1 in stack 302a and die 310a are labeled), which can communicatively couple to channel 1. Each bank group 320, 322, 324, 326 can include one or more memory banks (e.g., 8 memory banks) that each include one or more memory arrays. The other channels 2-7 (not shown) have similar configurations but communicatively couple to different bank groups in different dies. For example, the other channels may couple to BG4 through BG15.

In some embodiments, each channel 0-7 can be split into two pseudo-channels that operate semi-independently such as, for example, pseudo-channel PC0 corresponding to DQ bits 0-31 and pseudo-channel PC1 corresponding to DQ bits 32-64. The channels and/or pseudo-channels can provide independent access to corresponding BGs, where each BG can include one or more banks. For example, if a die has 16 banks, each BG can have four banks and an independent channel can provide access to that BG. A die can include fewer banks than 16 such as, for example, 4 banks, 8 banks, etc. In some embodiments, a die can include more than 16 banks. Similarly, the number of BGs in a die can be fewer or greater than four. Segmenting a memory device into banks and bank groups is known in the art and thus, for brevity, will not be further discussed. In addition, those skilled in the art understand that an HBM device can have different arrangements with respect to the number of dies, banks, bank groups, channels, and/or pseudo-channels than in the disclosed embodiments and still be consistent with the present disclosure.

The following description focuses on pseudo-channel PC0 in SID0 302a and DIE0 310a. However, the description is applicable to pseudo-channel PC1, the other stacks 302b-d, and the other dies 310b-d and 312a-d, and thus for brevity and clarity is not repeated. As seen FIG. 3B, the bank groups 320, 322, 324, and 326 are each split into two sets, with each set corresponding to a different pseudo-channel (PC0 or PC1). The banks groups 320 and 322 for the PC0 set can selectively and communicatively couple to the TSV bus for PC0 of channel 0. During read or write operations to a bank in either bank group 320 or 322, the HBM memory controller circuit 333 and/or another circuit determines which bank group the bank belongs to. Based on the determination, the HBM memory controller circuit 333 and/or another circuit selects the bank group and operatively couples the bank group to the TSV bus such that the bank group has access to the TSV bus for a period that is based on the t_{CCDS} CLK cycle period, which in some embodiments is 2 CLK cycles. During the t_{CCDS} CLK cycle period, another bank group cannot communicatively couple to that TSV bus.

A BG select circuit 334 (for clarity only the BG select circuit for PC0 in stack 302a of die 310a is labeled) selects which bank group (e.g., 320, 322) should communicatively couple to the TSV bus. In some embodiments, the determination as to which BG should be communicatively coupled to which TSV bus can be performed in the HBM memory controller circuit 333 (an/or another circuit in the HBM device) based on, for example, SID, BG, and/or BA information in the read/write commands. The BG select circuit 334 ensures only one of the bank groups 320 or 322 is communicatively coupled to the TSV bus at any given time. The BG select circuit 334, HBM memory controller circuit 333, and/or another circuit also ensures that the same bank group is not accessed within the t_{CCDL} CLK cycle period. The operational description for bank groups 320 and 322 corresponding to PC1 and the other bank groups 320 and 322 will be similar to that of bank groups 320 and 322 for PC0, and thus, for brevity, will not be discussed. In addition, the bank groups in the other dies 310b-d and 312a-d and in the other stacks 302b-d have similar configurations, and thus for brevity will not be discussed. Although the embodiment in FIG. 3B shows two BGs are first communicatively coupled to BG select circuit that is then communicatively coupled to the TSV bus, in other embodiments, based on the arrangement, each BG can communicatively couple directly to the TSV bus without the intervening BG select circuit. Those skilled in the art understand that the numbering and specific configuration of bank groups and banks can be different from that shown in FIGS. 3A and 3B, but the concepts discussed herein are applicable to other bank group configurations.

For brevity, embodiments having pseudo-channels are described below. However, those skilled in the art understand that the concepts discussed below are also applicable to embodiments where the channels are not split into pseudo-channels.

As seen FIG. 3B, interface die 332 includes the HBM memory controller circuit 333. The HBM memory controller circuit 333 controls external access to the DQ bus (e.g., from host device 120) and manages the DQ signals to and from the TSV bus based on the memory operation (e.g., read, write, etc.). Configuration and operation of HBM memory controller circuits are known to those skilled in the art and thus, for brevity, will not be discussed further.

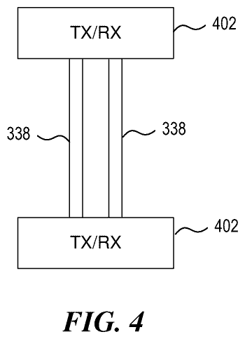

In the related art HBM device, the DQ bus and the TSV bus are synchronized so that the data rate through the buses are the same. For example, for an 8 Gbps data rate, the DQ bus and TSV bus timings are set based on the t_{CCDS} CLK cycle period, which is at 2 CLK cycles. The 2 CLK cycles correspond to a 1 ns transmission time through the TSV. However, if the data rate is increased, for example, doubled to 16 Gbps, the 2 CLK cycles now corresponds to a TSV bus transmission time of 0.5 ns. To keep the DQ bus and TSV bus synchronized, the frequency of the TSV bus must be increased to match that of the DQ bus. However, to drive the frequency higher, the transmitter and receiver circuits for the TSVs may have to be driven at a higher voltage. If the voltage is not high enough, the voltage swing between low and high voltage may not be fast enough due the electrical characteristics (e.g., resistance, inductance, ands capacitance) of the TSVs. For example, as seen in FIG. 4, the DQ signal TSVs 338 are driven by transmit/receive circuits 402 at each end of the TSV bus. If the voltage swing (between low and high voltage) of the signal in the TSV 338 is not fast enough at the higher frequency (e.g., 16 Gbps. 24 Gbps, 32 Gbps, etc.) due to the resistance, inductance, and/or capacitance characteristics of the TSV bus, the data carried by the signal will be corrupted. In such cases, the voltage setting at transmit/receive circuits 402 may need to be increased and/or low voltage swing signaling in the HBM device may need to be disabled. Accordingly, in some embodiments of the present disclosure, along with setting the TSV bus frequency to match that of the DQ bus, the transmit/receive circuits 402 of the TSV bus are configured such that the voltage source used to drive the signals through the TSB bus provides the proper voltage swing. For example, the voltage source in the transmit/receive circuits 402 can be configured to provide an upper voltage that is a range of 0.8 volts to 1.2 volts.

In some embodiments, to lower the power consumption and/or to aid in driving the TSV bus at the higher frequency, the dimensions of the TSVs can be changed to provide better electrical characteristics (e.g., resistance, inductance, and/or capacitance). For example, the diameter of the TSV can be in a range of 5 μm to 10 μm and the conductive materials used in the TSV bus can include one or more of copper, tungsten, and doped polysilicon.

However, in increasing the frequency, the timing stresses due to consecutive commands (e.g., read or write) associated with different bank groups in the same SID can be an issue. In related art HBM devices, consecutive commands to different bank groups in the same SID was permissible (e.g., see FIG. 2, which uses a command pattern of BG0/SID0 to BG1/SID0). However, with higher frequencies, the time duration of t_{CCDS} will decrease (e.g., from 1 ns to 0.5 ns if the data rate goes from 8 Gbps to 16 Gbps). With higher frequencies, consecutive commands to different bank groups in the same SID may cause gaps or bubbles in the DQ bus due to the tight timing margins. Accordingly, as discussed above, in some embodiments of the present disclosure, a new timing parameter t_{CCDS_SID} is introduced as a specification change for commands to different bank groups in the same SID. The new timing parameter t_{CCDS_SID} is defined as a delay between read or write commands associated with different bank groups in the same stack (SID). In some embodiments, t_{CCDS_SID} is a ratio of t_{CCDL}/t_{CCDS} and can be greater than 2. For example, the t_{CCDS_SID} CLK cycle period can be set at 4 CLK cycles, 6CLK cycles, 8 CLK cycles, or greater. When implemented, the host (e.g., host device 120), based on information communicated from the HBM device, and/or the HBM memory scheduler knows not to schedule commands (read or write) to different bank groups in the same SID during the t_{CCDS_SID} CLK cycle period. Thus, by using the new timing parameter t_{CCDS_SID}, the timing between commands to different banks groups in the same SID is more relaxed and the timing stresses may be mitigated. In some embodiments, the t_{CCDS_SID} parameter can be changed in firmware and/or the basic input/output system (BIOS) of the HDM device.

In operation, in some embodiments, the HBM memory controller circuit 333 and/or another circuit can select different bank groups from the stacks 302a-d in order to perform read or write operations during a t_{CCDL} CLK cycle period (e.g., 8 CLK cycles, 12 CLK cycles, 16 CLK cycles, etc.). For example, for a first t_{CCDS} CLK cycle period (e.g., 2 CLK cycles) within a t_{CCDL} CLK cycle period, the HBM memory controller circuit 333 can receive a read or write command corresponding to a bank. The HBM memory controller circuit 333 then determines the bank group corresponding to the bank and communicatively couples the bank group to the TSV bus for the duration of the t_{CCDS} CLK cycle period. Then, in each of the following t_{CCDS} CLK cycle periods (within the t_{CCDL} CLK cycle period), the process repeats for a different bank until the t_{CCDL} CLK cycle period ends. The different bank groups can correspond to the same channel (e.g., channel 0-7) or the same pseudo-channel (e.g., PC0 or PC1 for channel 0-7). During read or write operations, the HBM memory controller circuit 333 can selectively and communicatively couple the selected bank groups to the TSV bus corresponding to the channel or pseudo-channel. That is, each selected bank group is communicatively coupled to TSV bus one at a time to perform read or write operations to the appropriate bank. In some embodiments, each selected bank group is communicatively coupled to the TSV bus for duration of the respective t_{CCDS} CLK cycle period.

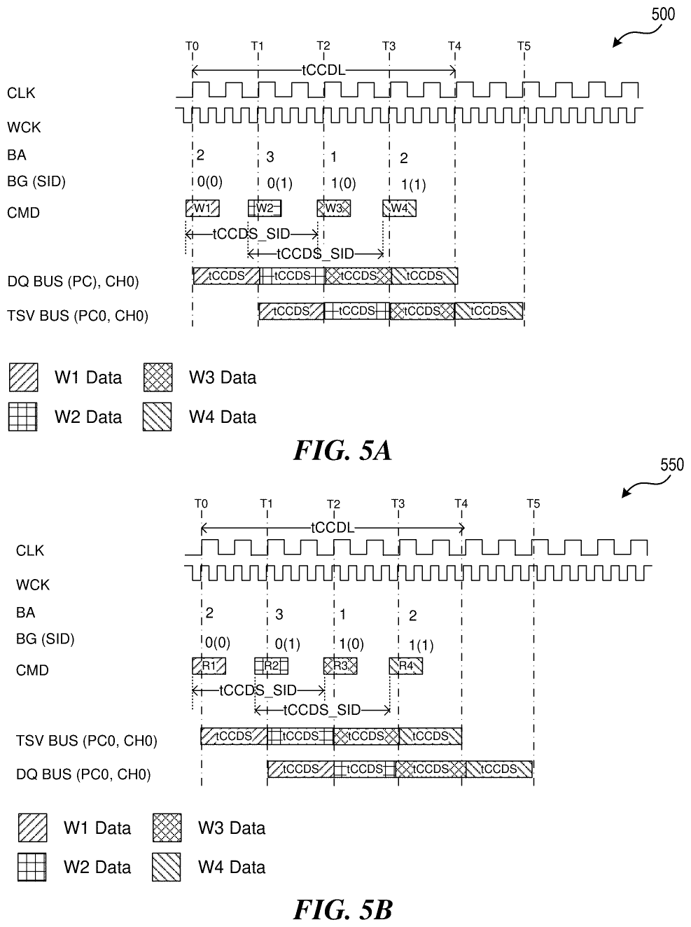

The timing diagrams of FIG. 5A and 5B can correspond to an HBM device that has a data rate of 16 Gbps. As seen in FIG. 5A and 5B, four bank groups can be selected for access to perform read or write operations during a t_{CCDL} CLK cycle period, which can be set at 8 CLK cycles to accommodate the four bank groups. As an illustrative example, the four bank groups can be BG 320 in die 310a, BG 320 in die 310b, BG 322 in die 310a, and BG 322 in die 310b which correspond to PC0 of channel 0. In some embodiments, the t_{CCDS} CLK cycle period can be set to 2 CLK cycles based on external communication requirements and to keep the DQ bus saturated. As seen in the diagram, the commands are separated by t_{CCDS} CLK cycles (2 CKL cycles). In addition, to match the data rate of the DQ bus, the TSV bus timing is also set at 2 CLK cycles. However, with respect to commands to different bank groups in the same SID, the t_{CCDS_SID} CLK cycle period is set to 8/2 =4CLK cycles. In this embodiment, with the data rate at 16 Gbps, a t_{CCDL} set at 8 CLK cycles corresponds to 2 ns time duration. With the t_{CCDL} time duration at 2 ns, the memory array timing of the related art HBM device discussed above does not need to be changed. Accordingly, in the above embodiment, the DQ bus timing, TSV bus timing, and the memory array timing are all synchronized.

FIG. 5A illustrates a simplified timing diagram 500 for write operations that are consistent with the present disclosure. As seen in the diagram and discussed further below, once a write command (e.g., write command W1) is issued by the host device (e.g., host device 120), the host device will wait t_{CCDS} CLK cycles (2 CLK cycles) before issuing another write command (e.g., write command W2) to a different bank group. For example, the W1 command writes to BG0/SID0 and the W2 command writes to BG0/SID1, which is a different bank group than BG0/SID0 because it is different stack. As seen in FIG. 5A, there are four consecutive commands (W1, W2, W3, and W4) that take t_{CCDL} CLK cycles (8 CLK cycles) to process. The write commands can alternate between bank groups of different stacks (e.g., the command sequence pattern can be SID0 to SID1 to SID0 to SID1). For clarity, the different W #data flows are identified using different hashlines and crosshatches.

The time from T0 to T4 corresponds to the timing parameter t_{CCDL}, which is 8 CLK cycles in this embodiment. As seen in FIG. 5A, 4 BGs can be opened (e.g., per channel or per pseudo-channel) for write operations during the t_{CCDL} CLK cycle period, which allows for more bandwidth than related art devices that only open 2 BGs. In the following embodiment, the banks being written to correspond to PC0 of channel 0 and thus, the TSV bus corresponds to PC0 of channel 0.

At time T0, based on a write command W1 to bank 2 of BG0 in SID0 with a BL of 8, 32 bytes of data are transmitted using 2 CLK cycles (4 WCK cycles) to the DQ bus from, for example, the host device 120 via HBM memory controller circuit 333. The 32-bytes for W1 can correspond to a pseudo-channel PC0 of channel 0 (e.g., based on the PC bit information in the address signal). At time T1, the W1 data is transferred to bank 2 over the TSV bus. As seen in FIG. 5A, once the transmission starts, the bank 2 has access to the TSV bus for t_{CCDS} CLK cycles, which in this case is 2 CLK cycles. In this embodiment, the 2 CLK cycles correspond to 0.5 ns, which means that the TSV bus is at the same data rate as the DQ bus.

Still at time T1, based on a write command W2 to bank 3 of BG 0 in SID1, 32 bytes of data are transmitted to the DQ bus after data transfer to the DQ bus for the write command W1 has finished. At time T2, the W1 data has completed the transfer over the TSV bus for BG 0 in SID0, and the W2 data is transferred to bank 3 over the TSV bus. Similar to the W1 write operation, once the transmission starts, bank 3 has access to the corresponding TSV bus for t_{CCDS} CLK cycles (e.g., 2 CLK cycles).

Still at time T2, based on a write command W3 to bank 1 of BG 1 in SID0, 32 bytes of data are transmitted to the DQ bus after the W2 data transfer to the DQ bus has finished. As seen in FIG. 5A, the W3 write command is scheduled (e.g., by the host device and/or HBM memory scheduler) t_{CCDS_SID} CLK cycles (e.g., 4 CLK cycles) after the W1 write command. Thus, the timing stresses related to back-to-back commands to the same SID is mitigated. At time T3, the W2 data has completed the transfer over the TSV bus for BG0 in SID1, and the W3 data is transferred to bank 1 over the TSV bus. Similar to the other write operations, once the transmission starts, bank 1 has access to the TSV bus for t_{CCDS} CLK cycles (e.g., 2 CLK cycles).

Still at time T3, based on a write command W4 to bank 2 of BG1 in SID1, 32 bytes of data are transmitted to the DQ bus after the W3 data transfer to the DQ bus has finished. As seen in FIG. 5A, the W4 write command is scheduled (e.g., by the host device and/or HBM memory scheduler) t_{CCDS_SID} CLK cycles (e.g., 4 CLK cycles) after the W2 write command. Thus, the timing stresses related to back-to-back commands to the same SID is mitigated. At time T4, W3 data has completed the transfer over the TSV bus for BG 1 in SID2, and the W4 data is transferred to bank 2 over the TSV bus. Similar to the other write operations, once the transmission starts, bank 2 has access to the TSV bus for t_{CCDS} CLK cycles (e.g., 2 CLK cycles). At time T5, the W4 data transfer to bank 2 of BG1 in SID1 has completed and the TSV bus is released.

FIG. 5B illustrates a simplified timing diagram 550 for read operations that are consistent with the present disclosure. As seen in the diagram and discussed further below, once a read command (e.g., read command R1) is issued by the host device (e.g., host device 120), the host device will wait t_{CCDS} CLK cycles (e.g., 2 CLK cycles) before issuing another read command (e.g., read command R2) to a different bank group. For example, the R1 command reads from BG0/SID0 and the R2 command reads from BG0/SID1, which is a different bank group than BG0/SID0 because it is different stack. As seen in 5B, there are four consecutive read commands (R1, R2, R3, and R4) that take t_{CCDL} CLK cycles (e.g., 8 CLK cycles) to process. The write commands can alternate between bank groups of different stacks (e.g., the command sequence pattern can be SID0 to SID1 to SID0 to SID1). For clarity, the different R #data flows are identified using different hashlines and crosshatches.

The time from T0 to T4 corresponds to the timing parameter t_{CCDL}, which is 8 CLK cycles in this embodiment. As seen in FIG. 5B, 4 BGs can be opened (e.g., per channel or per pseudo-channel) for read operations during the t_{CCDL} CLK cycle period, which allows for more bandwidth than related art devices that only open 2 BGs. In the following embodiment, the banks being read from correspond to PC0 of channel 0 and thus, the TSV bus corresponds to PC0 of channel 0.

At time T0, based on a read command R1, 32 bytes of data (BL of 8) are read from bank 2 of BG0 in SID0 and sent to the TSV bus. As seen in FIG. 5B, once the transmission starts, bank 2 has access to the TSV bus for t_{CCDS} CLK cycles, which in this case is 2 CLK cycles.

At time T1, the R1 data from bank 2 has completed the transfer to the TSV bus, and based on a read command R2, 32 bytes of data are read from bank 3 of BG0 in SID1 and sent to the TSV bus. As seen in FIG. 5B, once the transmission starts, bank 3 has access to the TSV bus for t_{CCDS} CLK cycles (e.g., 2 CLK cycles). Still at time T1, the R1 read data is made available on the DQ bus for t_{CCDS} CLK cycles (e.g., 2 CLK cycles) for transfer to, for example, the host device 120 via HBM memory controller circuit 333.

At time T2, the R2 data from bank 3 has completed the transfer over the TSV bus, and based on a read command R3, 32 bytes of data are read from bank 1 of BG1 in SID0 for transfer over the TSV bus. As seen in FIG. 5B, the R3 read command is scheduled (e.g., by the host device and/or HBM memory scheduler) t_{CCDS_SID} CLK cycles (e.g., 4 CLK cycles) after the R1 read command. Thus, the timing stresses related to back-to-back commands to the same SID is mitigated. Once the transmission starts, bank 1 has access to the TSV bus for t_{CCDS} CLK cycles (e.g., 2 CLK cycles). Still at time T2, the R2 read data is made available on the DQ bus for t_{CCDS} CLK cycles (e.g., 2 CLK cycles) for transfer to, for example, the host device 120 via HBM memory controller circuit 333.

At time T3, the data from bank 1 has completed the transfer over the TSV bus, and based on a read command R4, 32 bytes of data are read from bank 2 of BG 1 in SID3 for transfer over the TSV bus. As seen in FIG. 5B, the R4 read command is scheduled (e.g., by the host device and/or HBM memory scheduler) t_{CCDS_SID} CLK cycles (e.g., 4 CLK cycles) after the R2 read command. Thus, the timing stresses related to back-to-back commands to the same SID is mitigated. Once the transmission starts, bank 2 has access to the TSV bus for t_{CCDS} CLK cycles (e.g., 2 CLK cycles). Still at time T3, the R3 read data is made available on the DQ bus for t_{CCDS} CLK cycles (e.g., 2 CLK cycles) for transfer to, for example, the host device 120 via HBM memory controller circuit 333.

At time T4, the R4 read data transfer over the TSV bus from bank 2 of BG1 in SID3 is finished and the TSV bus is released. The R4 read data is made available on the DQ bus for t_{CCDS} CLK cycles (e.g., 2 CLK cycles) until time T5 for transfer to, for example, the host device 120 via HBM memory controller circuit 333.

As seen in FIGS. 5A and 5B, in embodiments of the present disclosure, the bandwidth can be increased while keeping the DQ bus saturated during read/write operations and while operating at a t_{CCDS} CLK cycle period equal to 2 CLK cycles. In addition, the introduction of the timing parameter t_{CCDS_SID} helps prevent back-to-back commands to the same SID, which can lessen the timing stresses.

To further relax the TSV bus timings, additional TSV buses can be added so that the channel or pseudo-channel has multiple TSV buses to provide multiple paths to select from when DQ data is transmitted to or received from the DRAMs. The multiple TSV buses allow for the data rate through each TSV bus to be lower while the total data rate across all the TSV buses matches that of the DQ bus. A bus switching circuit can be included in, for example, the interface die and configured such that the DQ bus can be selectively and communicatively coupled to one of the multiple TSV buses. In some embodiments, the DQ data can be split between the multiple buses such that DQ data corresponding to different commands (e.g., read or write) can be transmitted on different TSV buses. Thus, the frequency (and the voltage) driving the DQ signal through each TSV bus can be lower, which lowers power consumption in the HBM device. In some embodiments, the HBM device can use low swing signaling on the TSV buses.

To help synchronize the TSV bus timing and the memory array timing, instead of keeping the TSV bus timing at t_{CCDS} CLK cycles, as in some of the above embodiments, some embodiments of the present disclosure extend the TSV bus timings to be greater than t_{CCDS} CLK cycles, which provides the memory arrays more access time to the TSV bus.

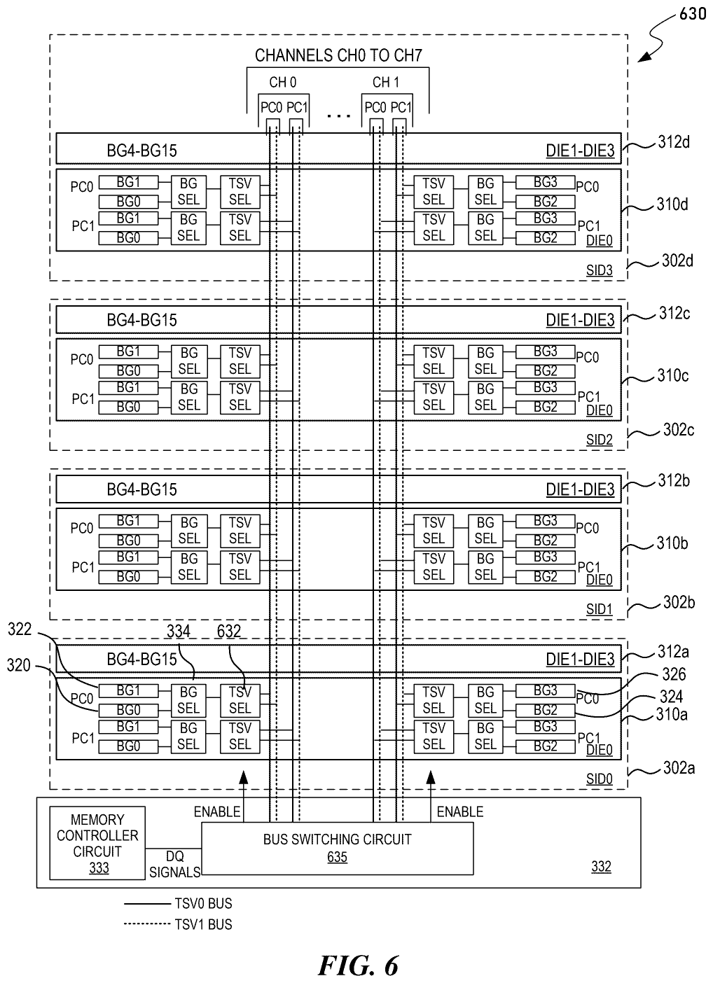

FIG. 6 illustrates an embodiment of an HBM device 630 with multiple TSV buses per DQ bus that is consistent with the present disclosure. HBM device 630 is similar to HBM device 330 and components that are the same are identified with the same reference numbers. Accordingly, for brevity, the functions of those components will not be discussed further. As seen in FIG. 6, each pseudo-channel has two TSV buses TSV 0 (solid line) and TSV1 (dotted line) (but other embodiments can have more TSV buses per channel, e.g., 3, 4, 5, 6, etc.). A bus switching circuit 635 to selectively and communicatively couple the DQ bus to the appropriate TSV bus can be included in, for example, the interface die. In addition, one or more TSV select circuits 632 can be included in each die (e.g., dies 310a-d and 312a-d) where each TSV select circuit 632 communicatively couples a bank group to the appropriate TSV bus. For clarity only one TSV select circuit 632 is labeled.

In some embodiments, a TSV select circuit 632 is included for each pseudo channel (or channel if not split into pseudo-channels) in each die. Each TSV select circuit 632 can be arranged between the BG select circuit 334 and the TSV buses TSV0 and TSV1. As discussed above, commands from, for example, a host device, can be associated with a bank in a bank group, such as, for example, bank group 320 or 322. Based on enable signals from, for example, the bus switching circuit 635 and/or another circuit, the TSV select circuit 632 can selectively and communicatively couple the appropriate bank group (e.g., either bank group 320 or 322) to either the TSV0 bus or the TSV1 bus.

Based on information from the HBM memory controller circuit 333, a host device (e.g., host device 120) and/or another circuit, the bus switching circuit 635 can select either the TSV0 bus or the TSV1 bus and communicatively couple the DQ bus to the selected TSV bus. After making a selection, the bus switching circuit 635 can send one or more enable signals to the appropriate TSV select circuit 632 so that the TSV select circuit 632 selects the appropriate TSV bus (TSV0 or TSV1). The selection of the buses can be based on a predetermined pattern, such as for example, alternating TSV buses after each command (or sequencing through TSV buses if there are more than two TSV buses). In other embodiments, the bus switching circuit 333 can determine if a TSV bus (e.g., a default bus) is busy before selecting a different bus.

As discussed above, the HBM device can be configured with timing parameter t_{CCDS_SID}, which introduces a delay between read or write commands associated with different bank groups in the same SID. In some embodiments, the relaxed TSV bus timing discussed above can be based on timing parameter t_{CCDS_SID}. For example, while the DQ bus timing can still be based on t_{CCDS} CLK cycles, the bus switching circuit 635 can be based on t_{CCDS_SID} CLK cycles, which can be set greater than the t_{CCDS} CLK cycles.

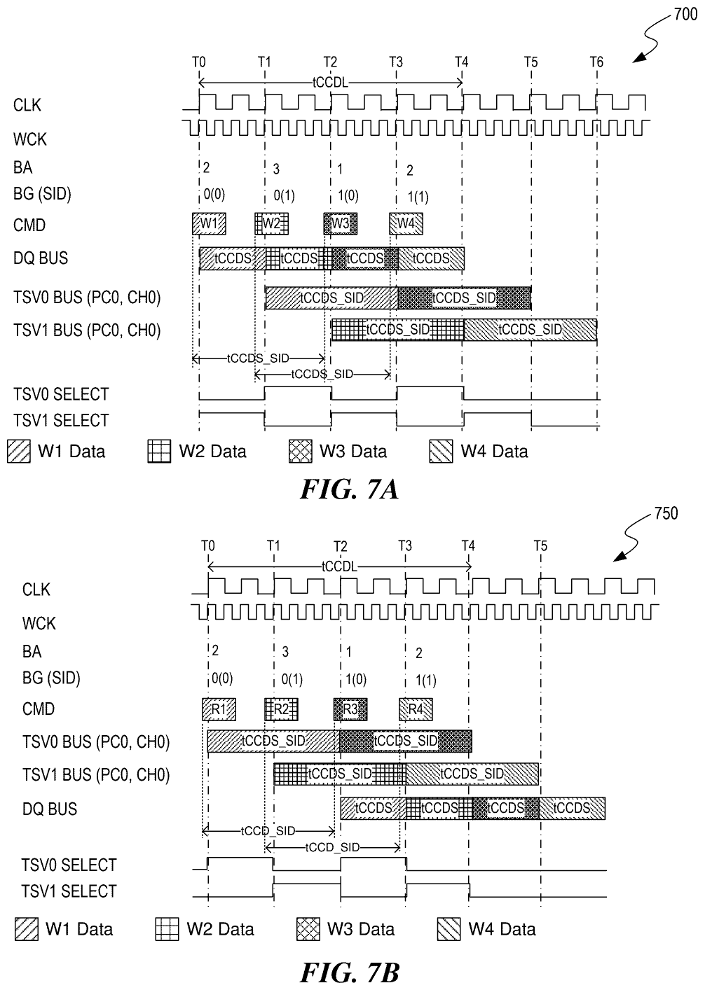

FIGS. 7A and 7B illustrate write and read operation timing diagrams 700 and 750, respectively, that are consistent with the present disclosure. The timing diagrams can correspond to an HBM device that has a data rate of 16 Gbps. For brevity, detailed discussions of the data flows are not provided, as they are similar to that given in FIGS. 5A and 5B. Similar to the embodiment of FIG. 5A and 5B, write and read commands to different bank groups in the same SID have a delay of t_{CCDS_SID} CLK cycles. For example, the W3 and W4 write commands are scheduled with a delay of t_{CCDS_SID} CLK cycles (e.g., 4 CLK cycles) after scheduling the corresponding W1 and W2 write commands, respectively. Similarly, the R3 and R4 read commands are scheduled with a delay of t_{CCDS_SID} CLK cycles (e.g., 4 CLK cycles) after scheduling the corresponding R1 and R2 read commands, respectively. Thus, similar to the embodiment of FIGS. 5A and 5B, the timing stresses due to selecting different bank groups in a same SID is mitigated.

However, in the embodiment of FIGS. 7A and 7B, there can be a further reduction in timing stresses because the memory arrays have more access time to the TSV bus than in the embodiment of FIGS. 5A and 5B. For example, in FIGS. 7A and 7B, the TSV bus access time can be based on t_{CCDS_SID} CKL cycles while the TSV bus access time in FIG. 5A and 5B can be based on t_{CCDS} CLK cycles. The DQ bus timing in both embodiments can be based on t_{CCDS} CLK cycles, The reduction in timing stresses can be achieved by alternating the command data between two TSV buses (TSV0 bus and TSV1 bus).

In some embodiments, the bus switching circuit 635 and/or another circuit can generate enable signals (e.g., TSV0 select and TSV1 select signals) that can be used by the bus switching circuit 635 and/or the TSV select circuits 632 to appropriately switch between the TSV0 and TSV1 buses. For example, as seen in FIGS. 7A and 7B, when the TSV0 select signal goes high, the TSV0 bus is select for data transmission, and when the TSV1 bus goes high, the TSV1 bus is selected for data transmission. In some embodiments, the switching frequency can be based on t_{CCDS_SID} CLK cycles. For example, in the embodiment of FIGS. 7A and 7B, each TSV bus can be selected every t_{CCDS_SID} CLK cycles (e.g., 4 CLK cycles), which can provide memory arrays more access time to the TSV buses than in the embodiment of FIGS. 5A and 5B, which provide an access time of t_{CCDS} CLK cycles (e.g., 2 CLK cycles). Accordingly, by using more TSV buses, the TSV bus timing stresses can be lower.

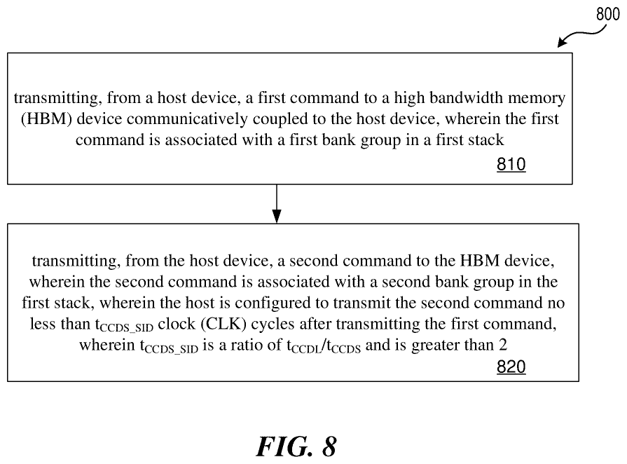

FIG. 8 illustrates a flow chart 800 showing the method steps performed by one or more processors and/or hardwired circuitry in host device such as, for example, host device 120. In step 810, the host device transmits a first command to a high bandwidth memory (HBM) device communicatively coupled to the host device, wherein the first command is associated with a first bank group in a first stack. For example, as discussed above, the host device can transmit read and write commands to bank groups associated with an in the HBM device (see, e.g., the W1 command and the R1 command to BG0 in SID0—see FIGS. 5A and 5B).

In step 820, the host device transmits a second command to the HBM device, wherein the second command is associated with a second bank group in the first stack, wherein the host is configured to transmit the second command no less than t_{CCDS_SID} clock (CLK) cycles after transmitting the first command, wherein t_{CCDS_SID} is a ratio of t_{CCDL}/t_{CCDS} and is greater than 2. As discussed above, the host device can transmit different read and write commands to a different bank group in the same SID after waiting a t_{CCDS_SID} CLK cycles (see, e.g., the W3 command and the R3 command to BG1 in SID0 transmitted after t_{CCDS_SID} CLK cycles—see FIGS. 5A and 5B). As discussed above, t_{CCDL} can be set to 8 CLK cycles and t_{CCDS} can be set to 2 CLK cycles. Thus, t_{CCDS_SID}, which is a ratio of t_{CCDL}/t_{CCDS} is 8/2, which equals 4 and is greater than 2.

From the foregoing, it will be appreciated that embodiment of the present disclosure provide increased bandwidth over related art HBM devices while ensuring that the DRAM memory array timings, the TSV bus timings, and the DQ bus timings are all synchronized. For example, it will be appreciated that, in some embodiment, the data rate at the DQ pins are increased while still keeping the same memory array as related art HBM devices. In addition, embodiments of the present disclosure increase the number of bank groups that can be opened during a t_{CCDL} duration in comparison to a related art HBM device, while still maintaining a 4N architecture and the same number of banks.

In addition, it will be appreciated that specific embodiments of the technology have been described herein for purposes of illustration, but well-known structures and functions have not been shown or described in detail to avoid unnecessarily obscuring the description of the embodiments of the technology. To the extent any material incorporated herein by reference conflicts with the present disclosure, the present disclosure controls. Where the context permits, singular or plural terms may also include the plural or singular term, respectively. Moreover, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Furthermore, as used herein, the phrase “and/or” as in “A and/or B” refers to A alone, B alone, and both A and B. Additionally, the terms “comprising,” “including,” “having,” and “with” are used throughout to mean including at least the recited feature(s) such that any greater number of the same features and/or additional types of other features are not precluded. Further, the terms “generally”, “approximately,” and “about” are used herein to mean within at least within 10 percent of a given value or limit. Purely by way of example, an approximate ratio means within ten percent of the given ratio.

Several implementations of the disclosed technology are described above in reference to the figures. The computing devices on which the described technology may be implemented can include one or more central processing units, memory, input devices (e.g., keyboard and pointing devices), output devices (e.g., display devices), storage devices (e.g., disk drives), and network devices (e.g., network interfaces). The memory and storage devices are computer-readable storage media that can store instructions that implement at least portions of the described technology. In addition, the data structures and message structures can be stored or transmitted via a data transmission medium, such as a signal on a communications link. Thus, computer-readable media can comprise computer-readable storage media (e.g., “non-transitory” media) and computer-readable transmission media.

It will also be appreciated that various modifications may be made without deviating from the disclosure or the technology. For example, the dies in the HBM device can be arranged in any other suitable order (e.g., with the non-volatile memory die(s) positioned between the interface die and the volatile memory dies; with the volatile memory dies on the bottom of the die stack; and the like). Further, one of ordinary skill in the art will understand that various components of the technology can be further divided into subcomponents, or that various components and functions of the technology may be combined and integrated. In addition, certain aspects of the technology described in the context of particular embodiments may also be combined or eliminated in other embodiments. For example, although discussed herein as using a non-volatile memory die (e.g., a NAND die and/or NOR die) to expand the memory of the HBM device, it will be understood that alternative memory extension dies can be used (e.g., larger-capacity DRAM dies and/or any other suitable memory component). While such embodiments may forgo certain benefits (e.g., non-volatile storage), such embodiments may nevertheless provide additional benefits (e.g., reducing the traffic through the bottleneck, allowing many complex computation operations to be executed relatively quickly, etc.).

Furthermore, although advantages associated with certain embodiments of the technology have been described in the context of those embodiments, other embodiments may also exhibit such advantages, and not all embodiments need necessarily exhibit such advantages to fall within the scope of the technology. Accordingly, the disclosure and associated technology can encompass other embodiments not expressly shown or described herein.

We claim:

1. A system-in-package (SiP) device, comprising:
a base substrate;
a processing unit carried by the base substrate; and
a high bandwidth memory (HBM) device carried by the base substrate and electrically coupled to the processing unit, the HBM device comprising a plurality of stacks, each stack comprising a plurality of bank groups associated with a same channel or a same pseudo-channel,
wherein the processing unit, based on a timing parameter communicated from the HBM device, is configured to transmit a first command to a first bank group associated with a first stack and configured to transmit a second command to a second bank group associated with the first stack no less than t_{CCDS_SID} clock (CLK) cycles after transmitting the first command,
wherein t_{CCDS_SID} is a ratio of t_{CCDL}/t_{CCDS} and is greater than 2, and
wherein t_{CCDL} corresponds to a delay between commands associated with different banks in a same bank group, and t_{CCDS} corresponds to a delay between commands associated with different banks in different bank groups.

2. The SiP device of claim 1, wherein the timing parameter is set in at least one of a firmware or a BIOS of the HBM device.

3. The SiP device of claim 1, wherein the HBM device further comprises,
a HBM memory controller circuit configured to select different bank groups from the plurality of bank groups during a t_{CCDL} CLK cycle period, each different bank group selected during different t_{CCDS} CLK cycle periods within the t_{CCDL} CLK cycle period,
wherein the HBM memory controller circuit is configured to selectively and communicatively couple a TSV bus to each selected bank group of the different bank groups, and the selected bank group is communicatively coupled to the TSV bus for a duration of the respective t_{CCDS} CLK cycle period.

4. The SiP device of claim 3, wherein the ratio of t_{CCDL}/t_{CCDS} is 4 and a data rate of the TSV bus is 16 gigabits per second (Gbps).

5. The SiP device of claim 3, wherein the different bank groups comprise four different bank groups, and wherein a data rate of the TSV bus is 16 Gbps.

6. The SiP device of claim 3, wherein the TSV bus is driven at a same data rate as that of a DQ bus, and wherein the data rate of the TSV bus is 16 Gbps, and
wherein a voltage source used to drive signals through the TSV bus provides an upper voltage in a range of 0.8 volts to 1.2 volts.

7. The SiP device of claim 6, wherein the HBM device comprises,
a plurality of TSV buses associated with a DQ bus corresponding to the channel or the pseudo-channel,
a bus switching circuit to select a TSV bus from the plurality of TSV buses and communicatively couple the selected TSV bus to the DQ bus, and
a TSV select circuit located in a die to communicatively couple the first bank group to the TSV bus.

8. A high bandwidth memory (HBM) device, comprising:
a plurality of stacks, each stack comprising a plurality of bank groups associated with a same channel or a same pseudo-channel; and
a HBM memory controller circuit configured to communicatively couple the plurality of stacks with a host device,
wherein the HBM device is configured with a timing parameter t_{CCDS_SID} that is defined as a delay in clock (CLK) cycles between commands from the host device that are associated with different bank groups in a same stack,
wherein the timing parameter t_{CCDS_SID} is a ratio of t_{CCDL}/t_{CCDS} and is greater than 2, and
wherein t_{CCDL} corresponds to a delay between commands associated with different banks in a same bank group, and t_{CCDS} corresponds to a delay between commands associated with different banks in different bank groups.

9. The HBM device of claim 8, wherein the timing parameter t_{CCDS_SID} is set in at least one of a firmware or a BIOS of the HBM device.

10. The HBM device of claim 8, wherein the HBM device further comprises,
a HBM memory controller circuit configured to select different bank groups from the plurality of bank groups during a t_{CCDL} CLK cycle period, each different bank group selected during different t_{CCDS} CLK cycle periods within the t_{CCDL} CLK cycle period,
wherein the HBM memory controller circuit is configured to selectively and communicatively couple a TSV bus to each selected bank group of the different bank groups, and the selected bank group is communicatively coupled to the TSV bus for a duration of the respective t_{CCDS} CLK cycle period.

11. The HBM device of claim 10, wherein the ratio of t_{CCDL}/t_{CCDS} is 4 and a data rate of the TSV bus is 16 gigabits per second (Gbps).

12. The HBM device of claim 10, wherein the different bank groups comprise four different bank groups, and wherein a data rate of the TSV bus is 16 Gbps.

13. The HBM device of claim 10, wherein the TSV bus is driven at a same data rate as that of a DQ bus, and wherein the data rate of the TSV bus is 16 Gbps, and
wherein a voltage source used to drive signals through the TSV bus provides an upper voltage in a range of 0.8 volts to 1.2 volts.

14. The HBM device of claim 13, wherein the HBM device comprises,
a plurality of TSV buses associated with a DQ bus corresponding to the channel or the pseudo-channel,
a bus switching circuit to select a TSV bus from the plurality of TSV buses and communicatively couple the selected TSV bus to the DQ bus, and
a TSV select circuit located in a die to communicatively couple a bank group to the TSV bus.

15. A method, comprising:
transmitting, from a host device, a first command to a high bandwidth memory (HBM) device communicatively coupled to the host device, wherein the first command is associated with a first bank group in a first stack; and
transmitting, from the host device, a second command to the HBM device, wherein the second command is associated with a second bank group in the first stack,
wherein the host is configured to transmit the second command no less than t_{CCDS_SID} clock (CLK) cycles after transmitting the first command,
wherein t_{CCDS_SID} is a ratio of t_{CCDL}/t_{CCDS} and is greater than 2, and
wherein t_{CCDL} corresponds to a delay between commands associated with different banks in a same bank group, and t_{CCDS} corresponds to a delay between commands associated with different banks in different bank groups.

16. The method of claim 15, wherein the ratio of t_{CCDL}/t_{CCDS} is 4.

17. The method of claim 15, wherein t_{CCDL} is 8 CLK cycles and t_{CCDS} is 2 CLK cycles.

18. The method of claim 15, wherein the ratio of t_{CCDL}/t_{CCDS} is set in at least one of a firmware or a BIOS of the HBM device.

19. The method of claim 15, wherein a communication data rate between the host device and the HBM device is 16 gigabits per second (Gbps).

20. The method of claim 15, wherein the host device and the HBM device are integrated into a system-in-package (SiP) configuration.
